(19) United States
(12) Patent Application Publication
(10) Pub. No.: US 2023/0301129 A1
(43) Pub. Date: Sep. 21, 2023

(54) SURFACE-FUNCTIONALIZED SILICON QUANTUM DOTS

(71) Applicant: THE CORETEC GROUP INC., Ann Arbor, MI (US)

(72) Inventor: Ramez Ahmed Elgammal, Knoxville, TN (US)

(21) Appl. No.: 18/007,804

(22) PCT Filed: Jun. 22, 2021
(86) PCT No.: PCT/US2021/038414

§ 371 Date: Dec. 2, 2022

Related U.S. Application Data
(60) Provisional application No. 63/042,068, filed on Jun. 22, 2020.

(51) Int. Cl. H10K 50/115; B82Y 30/00; C09K 11/59

(52) U.S. Cl. CPC H10K 50/115; B82Y 30/00; C09K 11/59; C09K 2211/1007; C09K 2211/1011; C09K 2211/1029; C09K 2211/1088

(57) ABSTRACT

A surface-modified quantum dot includes a silicon quantum dot, a polycyclic dye moiety, and a linking moiety that bonds the polycyclic dye moiety to the silicon quantum dot.

### BACKGROUND

Quantum dots (QDs), which are sometimes referred to as “artificial atoms,” are generally spherical semiconductor particles than range in size from about 1 nanometer to about 10 nanometers. The optical and electronic properties of QDs differ from bulk materials due to quantum mechanics. For instance, similar to a single atom, the electrons in QDs have bound, discrete electronic states. Energy input into a QD causes an electron to excite from the valence band to the conductance band. When the excited electron drops back into the valence band, the QD radiates light (photoluminescence) of a specific wavelength. The wavelength corresponds to the energy difference between the conductance band and the valence band, which depends on the composition, size, and surface properties of the QD. Even with next generation, direct band gap silicon QDs, however, there has been a challenge in creating QDs that generate light in the ultraviolet wavelength range, which is useful in microbial disinfection and numerous other applications.

### SUMMARY

A surface-modified quantum dot according to an example of the present disclosure includes a silicon quantum dot, a polycyclic dye moiety, and a linking moiety bonding the polycyclic dye moiety to the silicon quantum dot.

In a further embodiment of any of the foregoing embodiments, the linking moiety includes an amide moiety or a 1,2,3 triazole moiety.

In a further embodiment of any of the foregoing embodiments, the linking moiety includes an amide moiety.

In a further embodiment of any of the foregoing embodiments, the linking moiety includes a 1,2,3 triazole moiety.

In a further embodiment of any of the foregoing embodiments, the surface-modified quantum dot has a chemical structure as below, wherein Si-Dot is the silicon quantum dot and Dye is the polycyclic dye moiety:

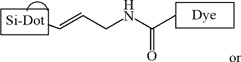

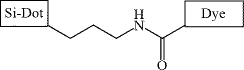

In a further embodiment of any of the foregoing embodiments, the surface-modified quantum dot has a chemical structure as below, wherein Si-Dot is the silicon quantum dot and Dye is the polycyclic dye moiety

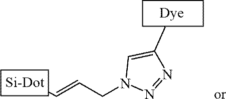

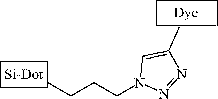

In a further embodiment of any of the foregoing embodiments, the polycyclic dye is selected from the group below consisting of a) through i) and combinations thereof:

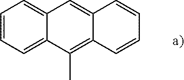

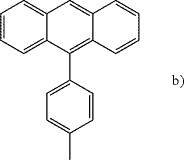 [SMILES: Cc1ccc(-c2c3ccccc3cc3ccccc23)cc1]

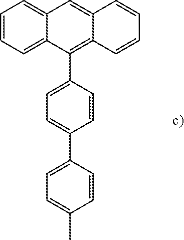 [SMILES: Cc1ccc(-c2ccc(-c3c4ccccc4cc4ccccc34)cc2)cc1]

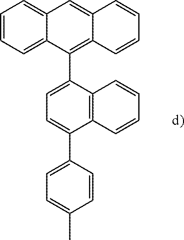 [SMILES: Cc1ccc(-c2ccc(-c3c4ccccc4cc4ccccc34)c3ccccc23)cc1]

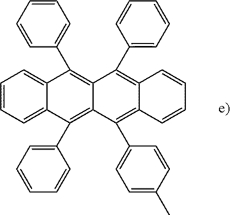 [SMILES: Cc1ccc(-c2c3ccccc3c(-c3ccccc3)c3c(-c4ccccc4)c4ccccc4c(-c4ccccc4)c23)cc1]

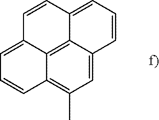 [SMILES: Cc1cc2cccc3ccc4cccc1c4c32]

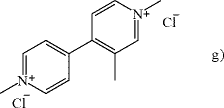

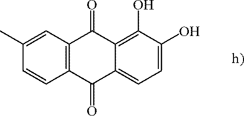 [SMILES: Cc1ccc2c(c1)C(=O)c1c(ccc(O)c1O)C2=O]

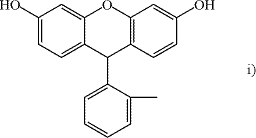 [SMILES: Cc1ccccc1C1c2ccc(O)cc2Oc2cc(O)ccc21]

In a further embodiment of any of the foregoing embodiments, the polycyclic dye moiety has from three to eight rings.

An optical device according to an example of the present disclosure includes one or more light emitting diodes (LEDs). Each of the one or more LEDs includes a plurality of surface-modified quantum dots according to any of the foregoing embodiments.

A method of fabricating a surface-modified quantum dot according to an example of the present disclosure includes functionalizing a hydrogen-terminated silicon quantum dot by substituting hydrogen of the hydrogen-terminated silicon quantum dot with an amine to produce an amino-functionalized silicon quantum dot. The method then includes reacting the amino-functionalized silicon quantum dot to bond a polycyclic dye thereto and thereby produce a surface-modified quantum dot having a linking moiety that bonds the polycyclic dye moiety to the silicon quantum dot.

In a further embodiment of any of the foregoing embodiments, the reacting includes conversion of the amino-functionalized silicon quantum dot to an azide-functionalized quantum dot.

In a further embodiment of any of the foregoing embodiments, the reacting includes contacting the amino-functionalized silicon quantum dot with a reactant selected from the group consisting of triflic azide, nonaflyl azide, and combinations thereof.

In a further embodiment of any of the foregoing embodiments, the reacting includes providing an alkyne-functionalized polycyclic dye, the alkyne-functionalized polycyclic dye reacting with the triazole-functionalized quantum dot to produce the surface-modified quantum dot with 1,2,3 triazole as the linking moiety.

In a further embodiment of any of the foregoing embodiments, the reacting includes providing a carboxylic acid-functionalized polycyclic dye. The carboxylic acid-functionalized polycyclic dye reacts with the amino-functionalized quantum dot to produce the surface-modified quantum dot with an amide as the linking moiety.

The present disclosure may include any one or more of the individual features disclosed above and/or below alone or in any combination thereof.

### BRIEF DESCRIPTION OF THE DRAWINGS

The various features and advantages of the present disclosure will become apparent to those skilled in the art from the following detailed description. The drawings that accompany the detailed description can be briefly described as follows.

FIG. 1 illustrates an example of a surface-modified silicon quantum dot.

FIG. 2 illustrates an optical device that includes surface-modified silicon quantum dots.

### DETAILED DESCRIPTION

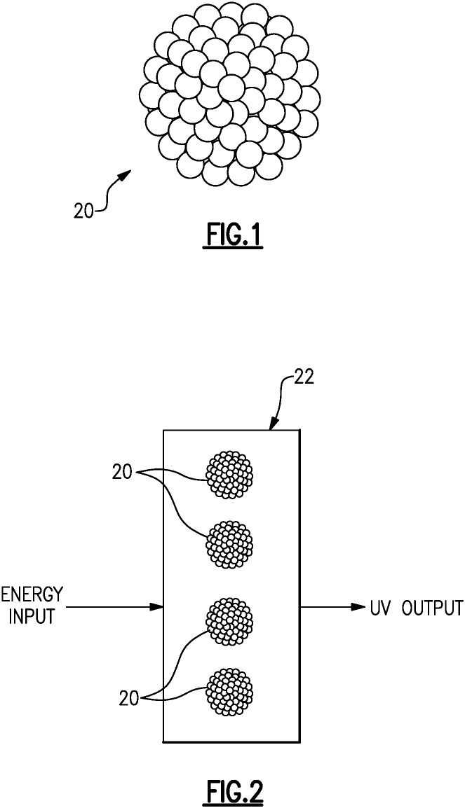

FIG. 1 illustrates an example of a surface-modified silicon quantum dot (QD) 20, and FIG. 2 illustrates an optical device 22 that incorporates a plurality of the QDs 20. As will be appreciated, the device 22 is shown in a highly schematic fashion and will include many orders of magnitude more of the QDs 20 than are shown. For example, the QDs 20 may be provided as a film, but are not limited thereto.

The QDs 20 are operable to generate output light in the ultraviolet wavelength range of the electromagnetic spectrum. As will be described below, the QDs 20 are surface-functionalized with dye molecules and can be fabricated by solution processing.

Example chemistries for the QDs 20 are shown below as Chemical Structure I, Chemical Structure II, Chemical Structure III, and Chemical Structure IV. Each of the structures has a silicon quantum dot (“Si-Dot”) and a polycyclic dye moiety (“Dye”). There is a linking moiety that covalently bonds the polycyclic dye moiety to the silicon quantum dot. In Chemical Structures I and III the linking moiety is 1,2,3- triazole, and in Chemical Structures II and IV the linking moiety is an amide. Chemical Structures III and IV are analogous to Chemical Structures I and II, respectively, with the difference being a single carbon-carbon tether on the surface of the Si-Dot as opposed to a double carbon-carbon bond.

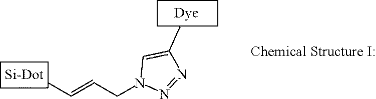

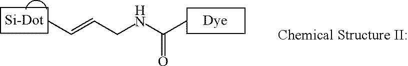

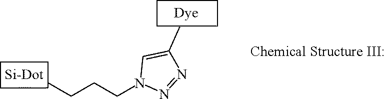

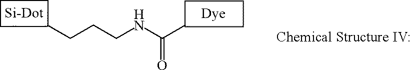

The polycyclic dye moiety is a ringed chemical structure that contains from three to eight rings. For example, some or all of the rings are aromatic rings. In another example one or more of the rings is heterocyclic with carbon and nitrogen forming the ring or rings. In general, the polycyclic dye moiety are ringed structures that are strongly absorbing and have an extinction coefficient of greater than 10,000 M⁻¹ cm⁻¹, such as an extinction coefficient from 50,000 to 100,000 M⁻¹ cm⁻¹. In further examples, the polycyclic dye is selected from the group below of a) through i) and combinations thereof.

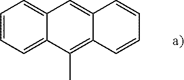

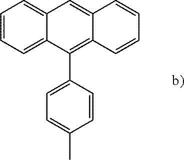 [SMILES: Cc1ccc(-c2c3ccccc3cc3ccccc23)cc1]

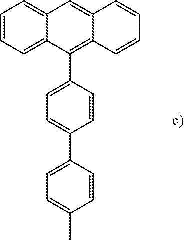 [SMILES: Cc1ccc(-c2ccc(-c3c4ccccc4cc4ccccc34)cc2)cc1]

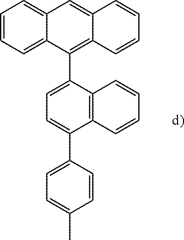 [SMILES: Cc1ccc(-c2ccc(-c3c4ccccc4cc4ccccc34)c3ccccc23)cc1]

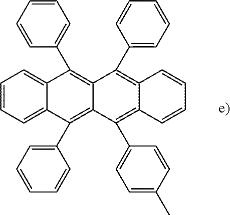 [SMILES: Cc1ccc(-c2c3ccccc3c(-c3ccccc3)c3c(-c4ccccc4)c4ccccc4c(-c4ccccc4)c23)cc1]

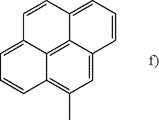 [SMILES: Cc1cc2cccc3ccc4cccc1c4c32]

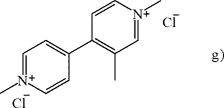

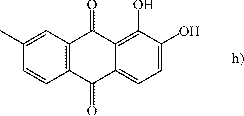 [SMILES: Cc1ccc2c(c1)C(=O)c1c(ccc(O)c1O)C2=O]

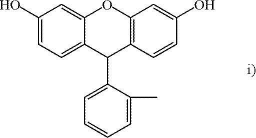 [SMILES: Cc1ccccc1C1c2ccc(O)cc2Oc2cc(O)ccc21]

Chemical Structure I and Chemical Structure II can be fabricated via solution processing. Example reaction pathways are shown below, where IA and IB are for Chemical Structure I, and IIA and IIB are for Chemical Structure II. Notably, a single silicon quantum dot may initially have many surface terminal groups. For example, the initial silicon quantum dot has 10-30 surface terminal hydrogen atoms. The hydrogen-terminated silicon quantum dot may be derived from cyclohexasilane, but is not limited thereto.

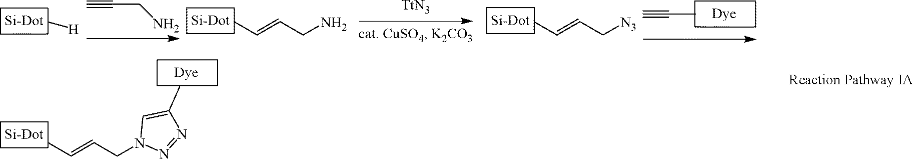

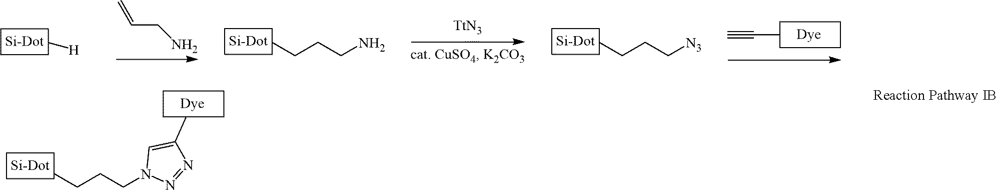

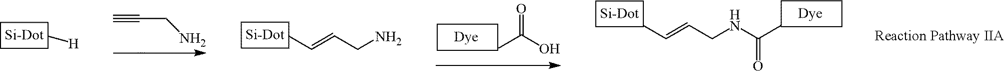

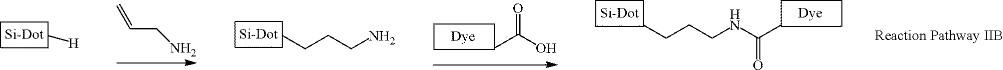

In each of the above reaction pathways, the initial step is the same, which is functionalization of the silicon quantum dot. The initial silicon quantum dot is functionalized with an amine to produce an amino-functionalized silicon quantum dot. For example, surface hydrogen of the silicon quantum dot is substituted with an amine, such as an alkyne amine or allyl amine.

After functionalization of the silicon quantum dot, for Reaction Pathway IA and Reaction pathway IB the amino-functionalized silicon quantum dot is then converted to an azide-functionalized silicon quantum dot. For example, the amino is reacted with triflic azide (or other inorganic or organic azide) in the presence of catalytic amounts of copper sulfate, or other similar copper I or copper II salts, (e.g., < 10 mol%). The azide-functionalized silicon quantum dot is then reacted with a functionalized polycyclic dye to produce the final surface-modified silicon quantum dot, with 1,2,3-triazole as the linking moiety.

After initial functionalization of the silicon quantum dot, for Reaction Pathway IIA and Reaction pathway IIB the amino of the amino-functionalized silicon quantum dot is converted to an amide. For example, the amino is reacted with a carboxylic acid-functionalized dye to produce the final surface modified silicon quantum dot, with an amide as the linking moiety.

The following examples demonstrate further, non-limiting aspects of fabrication.

### Example I: Initial Step

Hydrogen-terminated silicon quantum dots is suspended in mesitylene (or decane), 1 g per 50 ml of solvent. The alkyne (propargyl) or alkene (allyl amine) is then added. An assumption of 30 surface hydrogen groups per hydrogen-terminated silicon quantum dot gives 0.035 mmol necessary for stochiometric conversion and a range of amounts from 1 -10X. For 10X this is 350 mg of propargyl amine or 365 mg of allyl amine. The reaction is conducted under nitrogen cover gas and at 150° C. for 2-10 hours. The amino-functionalized silicon quantum dots are then collected by centrifugation. Optionally, the reaction is conducted with a radical initiator, such as AIBN (azobisisobutyronitrile) or TEMPO (2,2,6,6-tetramethylpiperidin-1-yl)oxidanyl) in 0.1 molar equivalent to the alkyne or alkene.

### Example II: Reaction Pathway IA and Reaction Pathway IB

The conversion of the amine to the azide is conducted using triflic azide or nonaflyl azide. The reactions from amine to triazole may be done sequentially or in one pot. To a suspension of the corresponding amine (0.6 mmol of amine) in water (3 mL) is added in sequence methanol (9 mL), sodium bicarbonate (2.5 mmol), a solution of nonafluorobutanesulfonyl azide (0.9 mmol) in ethanol (6 mL) and CuSO4·5H2O (0.06 mmol). The reaction mixture is stirred at room temperature for 6 h. Then, a terminal alkyne (0.65 mmol) and sodium ascorbate (0.9 mmol) are added and the reaction mixture is stirred at room temperature overnight. The triazole-functionalized silicon quantum dots are then collected by centrifugation, washed with water and methanol, and then dried under vacuum at 60° C.

### Example III: Reaction Pathway IIA and Reaction Pathway IIB

The amino-functionalized silicon quantum dots are suspended in n-Methyl-2-pyrrolidone (NMP), 1 gram per 50 mL of solvent. On a per mole basis of amine, 1.25 molar equivalents of carboxylic acid are added along with a coupling agent such as EDC (1-Ethyl-3-(3-dimethylaminopropyl)carbodiimide). The mixture is stirred at 25° C. for 4 hours and the amide-functionalized silicon quantum dots are then collected by centrifugation, washed with water and methanol, and then dried under vacuum at 60° C.

The surface-modified silicon quantum dots 20 disclosed herein are operable to emit ultraviolet light. Without wishing to be bound by any particular theory, the mechanism by which ultraviolet emission is thought to occur is photon upconversion based on triplet-triplet annihilation. In photon upconversion, two or more lower energy photons generated from the QDs 20 are converted to a single high-energy photon in the ultraviolet wavelength range. The specific wavelength may be “tuned” through choice of the initial silicon quantum dot size and chemistry of the dye moiety.

The QDs 20 may be incorporated into light-emitting diodes (LEDs) of functional devices, such as the optical device 22 of FIG. 2. For example, the device 22 may include a single LED, but more typically will include an array of LEDs. In some instances, the LED or LEDs may be incorporated into a cartridge or the like that can be installed into a device that enables operation of the LED or LEDs. Although the LEDs are expected to operate over lengthy ON/OFF cycles, it may be advantageous to replace LEDs if they become inoperable or under-performing. In this regard, the cartridge can be removed and replaced with a like cartridge that is new. Thus, a further aspect of this disclosure is the cartridge, a method of installing the cartridge into a device that enables operation of the LED or LEDs, and a method of removing a cartridge and installing a new cartridge in its place. Such methods may further include removal and replacement of one or more cartridges from a bank of cartridges in a common device that enables operation of the LED or LEDs.

Although a combination of features is shown in the illustrated examples, not all of them need to be combined to realize the benefits of various embodiments of this disclosure. In other words, a system designed according to an embodiment of this disclosure will not necessarily include all of the features shown in any one of the Figures or all of the portions schematically shown in the Figures. Moreover, selected features of one example embodiment may be combined with selected features of other example embodiments.

The preceding description is exemplary rather than limiting in nature. Variations and modifications to the disclosed examples may become apparent to those skilled in the art that do not necessarily depart from this disclosure. The scope of legal protection given to this disclosure can only be determined by studying the following claims.

What is claimed is:

1. A surface-modified quantum dot comprising:
a silicon quantum dot;
a polycyclic dye moiety; and
a linking moiety bonding the polycyclic dye moiety to the silicon quantum dot.

2. The surface-modified quantum dot as recited in claim 1, wherein the linking moiety includes an amide moiety or a 1,2,3 triazole moiety.

3. The surface-modified quantum dot as recited in claim 1, wherein the linking moiety includes an amide moiety.

4. The surface-modified quantum dot as recited in claim 1, wherein the linking moiety includes a 1,2,3 triazole moiety.

5. The surface-modified quantum dot as recited in claim 1, having a chemical structure below, wherein Si-Dot is the silicon quantum dot and Dye is the polycyclic dye moiety: 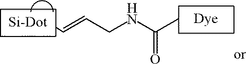 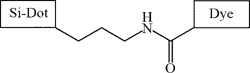
.

6. The surface-modified quantum dot as recited in claim 1, having a chemical structure below, wherein Si-Dot is the silicon quantum dot and Dye is the polycyclic dye moiety 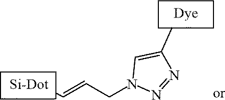 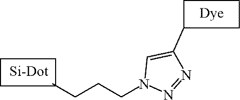
.

7. The surface-modified quantum dot as recited in claim 1, wherein the polycyclic dye is selected from the group below consisting of a) through i) and combinations thereof: 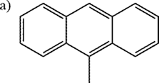 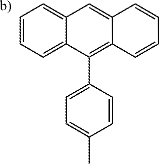 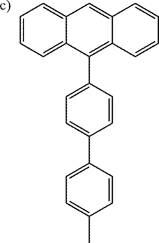 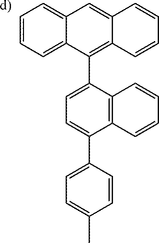 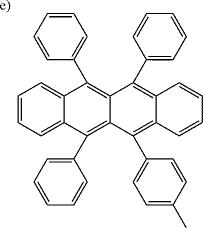 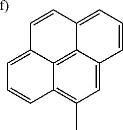 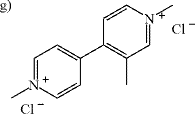 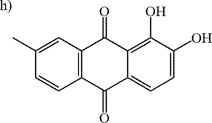 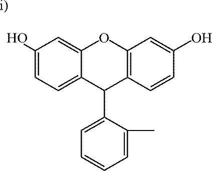
.

8. The surface-modified quantum dot as recited in claim 1, wherein the polycyclic dye moiety has from three to eight rings.

9. An optical device comprising:
one or more light emitting diodes (LEDs), each of the one or more LEDs including a plurality of surface-modified quantum dots, and each of the surface-modified quantum dots including:
a silicon quantum dot,
a polycyclic dye moiety, and
a linking moiety bonding the polycyclic dye moiety to the silicon quantum dot.

10. The optical device as recited in claim 9, wherein the linking moiety includes an amide moiety or a 1,2,3 triazole moiety.

11. The optical device as recited in claim 9, having a chemical structure below, wherein Si-Dot is the silicon quantum dot and Dye is the polycyclic dye moiety: 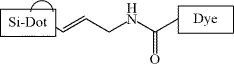
.

12. The optical device as recited in claim 9, having a chemical structure below, wherein Si-Dot is the silicon quantum dot and Dye is the polycyclic dye moiety 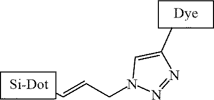
.

13. The optical device as recited in claim 9, wherein the polycyclic dye is selected from the group below consisting of a) through i) and combinations thereof: 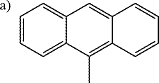 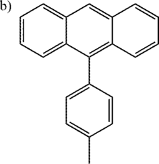 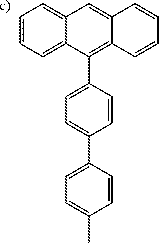 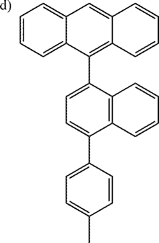 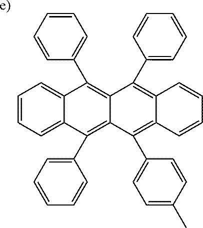 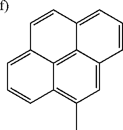 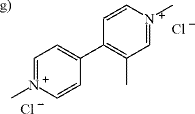 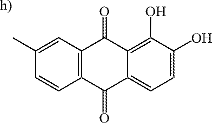 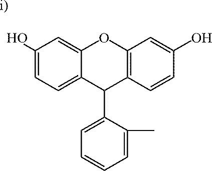
.

14. The optical device as recited in claim 9, wherein the polycyclic dye moiety has from three to eight rings.

15. A method of fabricating a surface-modified quantum dot, the method comprising:
functionalizing a hydrogen-terminated silicon quantum dot by substituting hydrogen of the hydrogen-terminated silicon quantum dot with an amine to produce an amino-functionalized silicon quantum dot;
reacting the amino-functionalized silicon quantum dot to bond a polycyclic dye thereto and thereby produce a surface-modified quantum dot having a linking moiety that bond the polycyclic dye moiety to the silicon quantum dot.

16. The method of claim 14, wherein the reacting includes conversion of the amino-functionalized silicon quantum dot to an azide-functionalized quantum dot.

17. The method as recited in claim 15, wherein the reacting includes contacting the amino-functionalized silicon quantum dot with a reactant selected from the group consisting of triflic azide, nonaflyl azide, and combinations thereof.

18. The method of claim 15, wherein the reacting includes providing an alkyne-functionalized polycyclic dye, the alkyne-functionalized polycyclic dye reacting with the triazole-functionalized quantum dot to produce the surface-modified quantum dot with 1,2,3 triazole as the linking moiety.

19. The method of claim 14, wherein the reacting includes providing a carboxylic acid-functionalized polycyclic dye, the carboxylic acid-functionalized polycyclic dye reacting with the amino-functionalized quantum dot to produce the surface-modified quantum dot with an amide as the linking moiety.
